(19) United States
(12) Patent Application Publication
(10) Pub. No.: US 2011/0266139 A1
(43) Pub. Date: Nov. 3, 2011

(54) FILM FORMING APPARATUS AND METHOD OF PRODUCING SUBSTRATE USING SAME

(75) Inventor: Yasuharu Matsumura, Tokyo (JP)

(73) Assignee: CANON ANELVA CORPORATION, Kawasaki-shi (JP)

(21) Appl. No.: 13/151,917

(22) Filed: Jun. 2, 2011

Related U.S. Application Data
(63) Continuation of application No. PCT/JP2009/007193, filed on Dec. 24, 2009.

(30) Foreign Application Priority Data
Dec. 26, 2008 (JP) 2008-332853

(51) Int. Cl. C23C 14/34; C23C 16/455; C23C 16/458; C23C 16/44

(52) U.S. Cl. 204/192.12; 118/719; 204/298.11

(57) ABSTRACT

The present invention provides a film forming apparatus that forms a film on a substrate (s) 1 being conveyed continuously in a vacuum chamber 7 under supply of a gas, wherein two film forming regions 14a and 14b can be readily supplied with a uniformly flowing gas simultaneously, and the film can be formed efficiently with high uniformity in film quality.

Provided is a film forming apparatus C, wherein a vacuum chamber 7 is divided by a partition plate 8 into a film forming chamber 9a including a conveying path for the substrate(s) 1 and an exhaust chamber 9b connected to an exhaust device 18; the film forming chamber 9a is provided with a gas supply portion 10, which is disposed on the opposite side of the partition plate 8 with the conveying path for the substrate(s) 1 between them and at a longitudinally center portion, and front and rear sputtering cathodes 12a and 12b which are disposed in the front and rear of the gas supply portion 10; and the partition plate 8 is provided with front and rear exhaust ports in the front of the front sputtering cathode 12a and in the rear of the rear sputtering cathode 12b.

### TECHNICAL FIELD

The present invention relates to a film forming apparatus that produces a film under supply of a gas by, for example, sputtering, vapor deposition, ion plating, plasma polymerization or the like, and a method of producing a substrate using it.

### BACKGROUND ART

A film is formed by, for example, sputtering, vapor deposition, ion plating, plasma polymerization or the like under supply of a gas into a vacuum chamber. Therefore, it is important to flow the gas uniformly in the vacuum chamber in order to secure uniform film quality. Especially, it is important for reactive film forming (e.g., forming a protective film of SiN) to have the gas uniformly in a film forming region in order to secure uniform film quality.

Conventionally, there is a known film forming apparatus for continuously forming a film on a long substrate being conveyed continuously in a vacuum chamber by sputtering using a reactive gas, wherein a target and a sputtering gas supply orifice are provided at one side in the vacuum chamber with a substrate conveying path determined as a boundary within the vacuum chamber, a reactive gas supply orifice is disposed to supply the reactive gas to the film forming region which is sandwiched between the target and the substrate conveying path, and an exhaust port is disposed at a position facing the reactive gas supply orifice (e.g., see FIG. 2 of Patent Reference 1).

### PRIOR ART REFERENCE

### Patent Reference

[Patent Reference 1] JP-A 06-116722

### SUMMARY

### Problems to be Solved by the Invention

In the above-described conventional film forming apparatus, the reactive gas supply orifice and the exhaust port are mutually opposed directly on the same side with the film forming region between them in the vacuum chamber having the substrate conveying path as the boundary. Therefore, a retaining part of the reactive gas is not generated easily, but the reactive gas coming out of the reactive gas supply orifice flows linearly to the exhaust port and is hard to expand to right and left sides. Therefore, there is a problem that the reactive gas of the film forming region is apt to have changes in concentration.

It is considered to increase a film-forming speed by disposing two targets, two sputtering gas supply orifices, two reactive gas supply orifices and two exhaust ports in one vacuum chamber, but it is necessary to control the supply and discharge of the reactive gas at two positions simultaneously, and there is a problem that the control becomes complex.

In view of the existing disadvantages described above, the present invention provides a film forming apparatus that forms a film on substrates being conveyed continuously in a vacuum chamber under supply of a gas, wherein the gas is readily supplied to two film forming regions simultaneously by uniformly flowing, and the film with high uniformity in film quality can be formed efficiently.

### Means for Solving the Problem

For the above object, the invention provides a film forming apparatus for forming a film on a long substrate being conveyed continuously in a vacuum chamber or substrates being placed on and conveyed continuously by trays moving continuously in the vacuum chamber under supply of a gas, wherein:

the vacuum chamber is divided by a partition plate into a film forming chamber including a conveying path for the substrate(s) and an exhaust chamber connected to an exhaust device;

the film forming chamber is provided with a gas supply portion, which is disposed on the opposite side of the partition plate with the conveying path for the substrate(s) between them and at a longitudinally center portion, and front and rear film forming portions which are disposed in the front and rear of the gas supply portion; and

the partition plate is provided with a front exhaust port and a rear exhaust port in the front of the front film forming portion and in the rear of the rear film forming portion.

The invention also includes as preferable embodiments that the front film forming portion and the front exhaust port, and the rear film forming portion and the rear exhaust port are disposed symmetrically in a longitudinal direction and a widthwise direction;

the front and rear film forming portions are portions for forming the film by sputtering and provided with front and rear sputtering cathodes which are opposed to the conveying path for the substrate(s), and front and rear film forming regions, which are opposed regions of the front and rear sputtering cathodes and the conveying path for the substrate(s), are surrounded by front and rear cathode-side shields with a space remained with respect to the conveying path for the substrate(s); and

the front and rear film forming regions each have a width larger than that of the conveying path for the substrate(s), and a conveying path-side shield is disposed along a position on the partition plate corresponding to the outside of the both ends in the widthwise direction of the front and rear film forming regions with a space remained against the front and rear cathode-side shields.

A method of producing a substrate(s) using the above film forming apparatus is also provided.

According to the invention, the front indicates an upstream of the flow of substrates being conveyed in the vacuum chamber and the rear indicates a downstream, and the conveying path for the substrates indicates a passing region in the vacuum chamber for a long substrate conveyed without using a tray or continuous trays and substrates placed on and conveyed by them. And, the widthwise direction indicates a direction that is parallel to the surface of the substrate conveyed in the vacuum chamber and perpendicular to the direction of conveying the substrate, and the width indicates a size in the widthwise direction.

### Effects of the Invention

In the vacuum chamber of the film forming apparatus according to the invention, the gas supplied from the gas supply portion is flown mainly through the film forming regions of the front and rear film forming portions, entered into the exhaust chamber through the front and rear exhaust ports and discharged, and the gas can be supplied from one gas supply portion to two film forming regions at the same time. Since the gas flow can be readily adjusted by adjusting the positions and sizes of the front and rear exhaust ports, the gas can be supplied easily and uniformly to the film forming regions of the front and rear film forming portions. Therefore, the film can be formed efficiently with high uniformity in film quality.

### BRIEF DESCRIPTION OF THE DRAWINGS

FIG. 1 is a schematic longitudinal sectional view showing an example of the film forming apparatus according to the invention.

FIG. 2 is a schematic transverse sectional view along a substrate conveying path of the film forming apparatus shown in FIG. 1.

FIG. 3 is a schematic transverse sectional view of the film forming apparatus shown in FIG. 1 with its top external wall portion removed horizontally.

FIG. 4 is a side view showing an example of trays continuously moving with substrates on them.

### DETAILED DESCRIPTION OF THE INVENTION

An embodiment of the invention is described below with reference to the drawings.

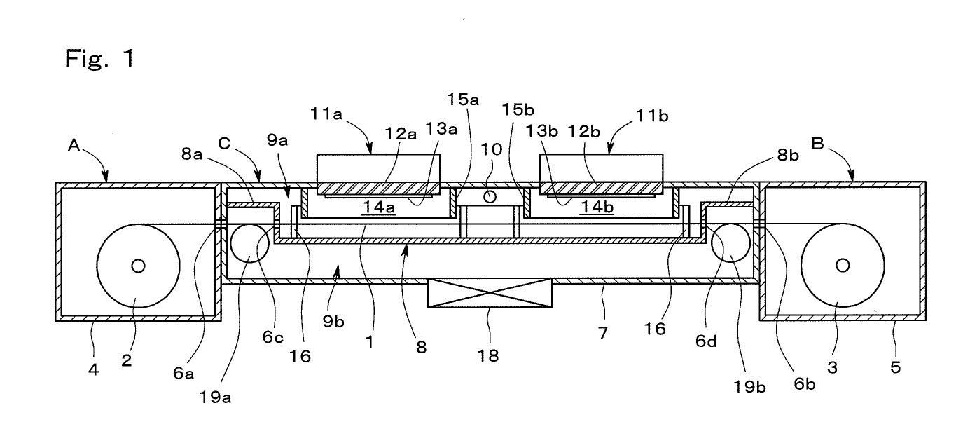

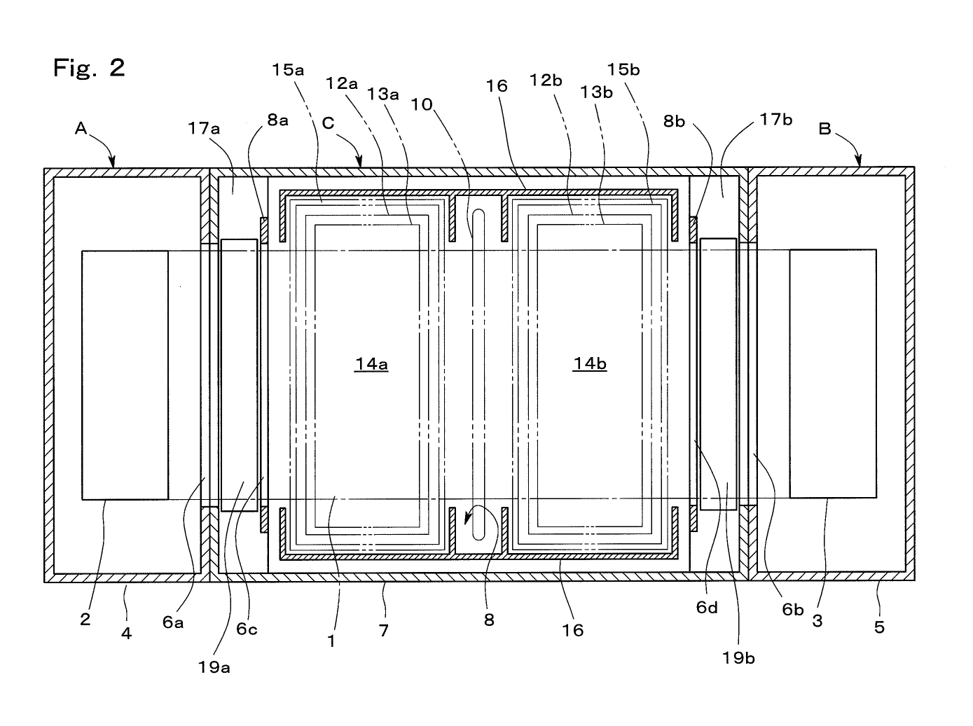

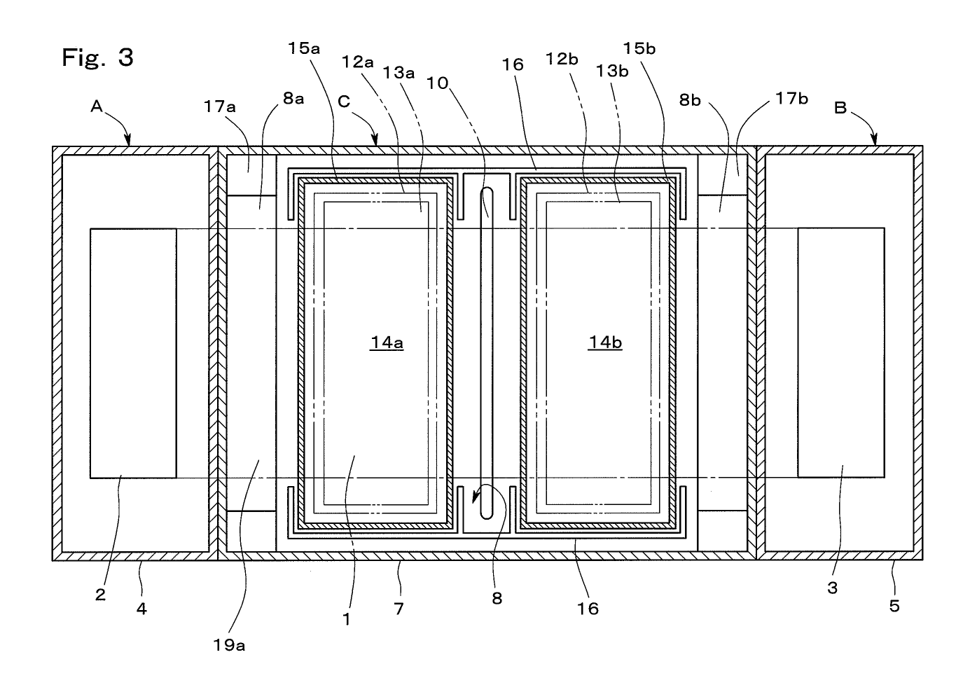

FIG. 1 is a schematic longitudinal sectional view showing an example of the film forming apparatus according to the invention. FIG. 2 is a schematic transverse sectional view along a substrate conveying path of the film forming apparatus shown in FIG. 1. FIG. 3 is a schematic transverse sectional view of the film forming apparatus shown in FIG. 1 with its top external wall portion removed horizontally.

A substrate 1 of this embodiment is a long sheet and fed from a feed roll 2 on the left side in the drawing and wound on a take-up roll 3 on the right side. A is a feeding apparatus having the feed roll 2 therein, B is a wind-up apparatus having the take-up roll 3 therein, and C is a film forming apparatus according to this embodiment which is disposed between the feeding apparatus A and the wind-up apparatus B.

Vacuum chambers 4 and 5 of the feeding apparatus A and the wind-up apparatus B each are connected to a vacuum chamber 7 of the film forming apparatus C through slits 6a and 6b. The substrate 1 pulled out from the feed roll 2 is pulled into the vacuum chamber 7 through the slit 6a, continuously conveyed in the vacuum chamber 7, and wound on the take-up roll 3 through the slit 6b.

The inside of the vacuum chamber 7 of the film forming apparatus C is horizontally divided into two sections by a partition plate 8. In FIG. 1, the upper section is a film forming chamber 9a, and the lower section is an exhaust chamber 9b.

The film forming chamber 9a includes at least a longitudinally center portion of a conveying path for the substrate 1 within the vacuum chamber 7 of the film forming apparatus C. And, the film forming chamber 9a is provided with a gas supply portion 10 at the longitudinally center portion and on the opposite side of the partition plate 8 with the conveying path for the substrate 1 between them. This gas supply portion 10 flows the gas which is supplied from a gas supply source (not shown) into the film forming chamber 9a, to supply to front and rear film forming regions 14a and 14b described later. In the film forming chamber 9a, the film is formed under supply of the gas from the gas supply portion 10.

The gas supply portion 10 can also flow the gas in four directions but, since the gas flow to the front and rear film forming regions 14a and 14b described later can be uniformized easily, it is preferable that the gas is flown out from a linear or dotted line position, which crosses the conveying path for the substrate 1, toward the substrate 1. Specifically, a tube member having a slit or multiple small holes formed in the axial direction can be arranged with the slit or the small holes directed to the conveying path for the substrate 1.

And, front and rear film forming portions 11a and 11b are provided on the opposite side of the partition plate 8 with the conveying path for the substrate 1 in the film forming chamber 9a between them and at the front and rear of the gas supply portion 10. The front and rear film forming portions 11a and 11b are portions provided with a mechanism of forming particles used to form the film by adhering to the substrate 1, and the front and rear film forming portions 11a and 11b of this embodiment are portions to form the film by sputtering. That is, the front and rear film forming portions 11a and 11b of this embodiment are provided with front and rear sputtering cathodes 12a and 12b which are opposed to the conveying path for the substrate 1. And, 13a and 13b are targets which are attached to the front and rear sputtering cathodes 12a and 12b to oppose to the conveying path for the substrate 1.

Opposed regions of the front and rear sputtering cathodes 12a and 12b and the conveying path for the substrate 1 configure the front and rear film forming regions 14a and 14b capable of forming the films on the substrate 1. The front and rear film forming regions 14a and 14b are surrounded by front and rear plate-like cathode-side shields 15a and 15b, which are protruded from an inner wall surface of the vacuum chamber 7, with a space left against the conveying path for the substrate 1. The front and rear cathode-side shields 15a and 15b are not essential structures but it is preferable to dispose them because the gas having entered from the space between the substrate 1 and the front and rear cathode-side shields 15a and 15b into the front and rear film forming regions 14a and 14b is easily retained temporarily, and the gas concentrations in the front and rear film forming regions 14a and 14b are easily uniformized. And, sputtering particles can also be prevented from being dispersed out of the front and rear film forming regions 14a and 14b by the front and rear cathode-side shields 15a and 15b.

In this embodiment, the front and rear sputtering cathodes 12a and 12b and the front and rear film forming regions 14a and 14b have a width larger than that of the conveying path for the substrate 1 such that a uniform film is formed easily along the full width of the substrate 1. A continuous conveying path-side shield 16 is disposed on the right and left sides along a position on the partition plate 8 corresponding to the outside of the both ends in the widthwise direction and protruded externally from the conveying path for the substrate 1 of the front and rear film forming regions 14a and 14b with a space remained against the front and rear cathode-side shields 15a and 15b. The conveying path-side shields 16 are not essential structures either, but it is preferable to provide them because the gas flow is suppressed from making short cut from the ends in the widthwise direction of the substrate 1 to front and rear exhaust ports 17a and 17b described later, and the gas concentration in the front and rear film forming regions 14a and 14b can be made more uniform.

The partition plate 8 is provided with the front exhaust port 17a and the rear exhaust port 17b in the front of the front film forming portion 11a and in the rear of the rear film forming portion 11b. The front exhaust port 17a and the rear exhaust port 17b are preferably disposed symmetrically in the longitudinal direction and the widthwise direction so that the gas flows at front and rear portions in the film forming chamber 9a become same. And, it is also preferable in view of the same reason as above that the above-described front film forming portion 11a and the rear film forming portion 11b are disposed symmetrically in the longitudinal direction and the widthwise direction. It is also preferable that the above-described front and rear cathode-side shields 15a and 15b and the conveying path-side shields 16 are disposed symmetrically in the longitudinal direction and the widthwise direction.

The front and rear exhaust ports 17a and 17b of this embodiment are provided at four corners as shown in FIG. 2 and FIG. 3 but can also be provided at the center portion in the widthwise direction.

An exhaust device 18 such as a vacuum pump is connected to the exhaust chamber 9b formed below the partition plate 8, so that the gas flowing from the film forming chamber 9a to the exhaust chamber 9b through the front and rear exhaust ports 17a and 17b can be exhausted.

Front and rear ends of the partition plate 8 are protruded toward the film forming chamber 9a to configure roller cover portions 8a and 8b. Guide rollers 19a and 19b are disposed on the side of the exhaust chamber 9b in the roller cover portions 8a and 8b. And the substrate 1 is once entered into the exhaust chamber 9b at its front and rear, and supported and conveyed by the guide rollers 19a and 19b.

Slits 6c and 6d which allow the passage of the substrate 1 are formed at the intersecting portions of the above-described roller cover portions 8a and 8b with the conveying path for the substrate 1. The guide rollers 19a and 19b are prepared within the film forming chamber 9a, and the slit 6a which communicates the vacuum chamber 4 of the feeding apparatus A and the vacuum chamber 7 of the film forming apparatus C and the slit 6b which communicates the vacuum chamber 7 of the film forming apparatus C and the vacuum chamber 5 of the wind-up apparatus B are formed in the film forming chamber 9a, so that the roller cover portions 8a and 8b and the slits 6c and 6d can be omitted. But, it is preferable to configure as described above, because the two slits 6a and 6c are provided between the feeding apparatus A and the film forming chamber 9a, the two slits 6b and 6d can also be provided between the film forming chamber 9a and the wind-up apparatus B, and barrier properties of the film forming chamber 9a against the feeding apparatus A and the wind-up apparatus B are improved.

According to the film forming apparatus C of this embodiment, the vacuum chamber 7 (film forming chamber 9a and exhaust chamber 9b) is decompressed to a predetermined degree of vacuum, its evacuation by the exhaust device 18 is continued, and the targets of the front and rear film forming portions 11a and 11b are sputtered under supply of the gas from the gas supply portion 10. Thus, a thin film can be formed continuously on the surfaces of the substrates 1 being conveyed.

As the gas supplied from the gas supply portion 10, there is used, for example, nitrogen when a film of titanium nitride (TiN) is formed or oxygen when a film of indium tin oxide (ITO) is formed. The gas supplied from the gas supply portion may be any of a sputtering gas, a processing gas or a mixture gas of them. When only the processing gas is supplied from the gas supply portion 10, a different sputtering gas supply portion may be provided near the front and rear sputtering cathodes 12a and 12b.

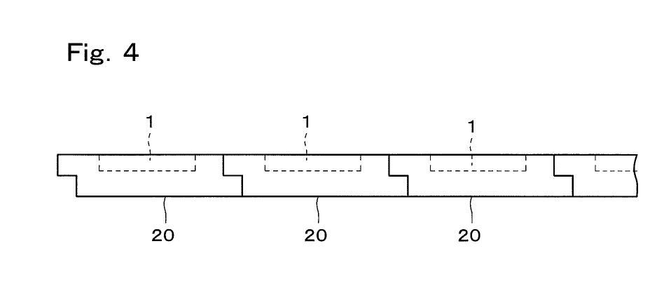

In the above embodiment, the substrate 1 has a long shape, but even when the substrate 1 itself is not long, the film forming apparatus C of the invention can also be applied when the substrates 1 are placed on and continuously conveyed by trays 20 which are continuously moved as shown in FIG. 4.

In the above embodiment, the top is the film forming chamber 9a and the bottom is the exhaust chamber 9b. But it can also be determined that the top is the exhaust chamber 9b and the bottom is the film forming chamber 9a, and when the substrate 1 is conveyed in a state erected in the widthwise direction, the film forming chamber 9a and the exhaust chamber 9b can also be formed on the right and left sides of the conveying direction.

In the above embodiment, the front and rear film forming portions 11a and 11b are portions where the film is formed by sputtering but can also be portions where the film is formed by vapor deposition, ion plating, plasma polymerization or the like.

### EXPLANATION OF REFERENCE NUMERALS

A: feeding apparatus, B: wind-up apparatus, C: film forming apparatus, 1: substrate, 2: feed roll, 3: take-up roll, 4: vacuum chamber (of feeding apparatus), 5: vacuum chamber (of wind-up apparatus), 6a: slit, 6b: slit, 6c: slit, 6d: slit, 7: vacuum chamber (of film forming apparatus), 8: partition plate, 8a: roller cover portion, 8b: roller cover portion, 9a: film forming chamber, 9b: exhaust chamber, 10: gas supply portion, 11a: front film forming portion, 11b: rear film forming portion, 12a: front sputtering cathode, 12b: rear sputtering cathode, 13a: target, 13b: target, 14a: front film forming region, 14b: rear film forming region, 15a: front cathode-side shield, 15b: rear cathode-side shield, 16: conveying path-side shield, 17a: front exhaust port, 17b: rear exhaust port, 18: exhaust device, 19a: guide roller, 19b: guide roller, 20: tray

What is claimed is:

1. A film forming apparatus for forming a film on a substrate (s) being conveyed in a vacuum chamber under supply of a gas, wherein:
the vacuum chamber is divided by a partition plate into a film forming chamber including a conveying path for the substrate(s) and an exhaust chamber connected to an exhaust device;
the film forming chamber is provided with front film forming portion and rear film forming portion, which are disposed on the opposite side of the partition plate with the conveying path for the substrate(s) between them, and a gas supply portion which is disposed between the front film forming portion and the rear film forming portion; and
the partition wall is provided with a front exhaust port and a rear exhaust port in the front of the front film forming portion and in the rear of the rear film forming portion.

2. The film forming apparatus according to claim 1, wherein the front film forming portion and the front exhaust port, and the rear film forming portion and the rear exhaust port are disposed symmetrically in a longitudinal direction and a widthwise direction.

3. The film forming apparatus according to claim 1 or 2, wherein the front and rear film forming portions are portions for forming the film by sputtering and provided with front and rear sputtering cathodes which are opposed to the conveying path for the substrate(s), and front and rear film forming regions, which are opposed regions of the front and rear sputtering cathodes and the conveying path for the substrate(s), are surrounded by front and rear cathode-side shields with a space remained with respect to the conveying path for the substrate(s).

4. The film forming apparatus according to claim 3, wherein the front and rear film forming regions each have a width larger than that of the conveying path for the substrate(s), and a conveying path-side shield is disposed along a position on the partition plate corresponding to the outside of the both ends in the widthwise direction of the front and rear film forming regions with a space remained against the front and rear cathode-side shields.

5. A method of producing a substrate having a thin film on its surface, wherein the thin film is formed by the film forming apparatus according to any one of claims 1 to 4.
